(19) United States
(12) Patent Application Publication
(10) Pub. No.: US 2026/0219128 A1
(43) Pub. Date: Jul. 30, 2026

(54) Wide-Area Leak Detection System

(71) Applicant: Joshua Windmiller, San Diego, CA (US)

(72) Inventor: Joshua Windmiller, San Diego, CA (US)

(21) Appl. No.: 19/452,368

(22) Filed: Jan. 18, 2026

Related U.S. Application Data
(60) Provisional application No. 63/749,540, filed on Jan. 25, 2025.

(51) Int. Cl. G01M 3/40; H05K 1/11

(52) U.S. Cl. CPC G01M 3/40; H05K 1/113

(57) ABSTRACT

A wide area leak detection system and device are disclosed herein. The system has a planar substrate with an electrically conducting material on both an anterior and posterior surfaces, with through vias forming columnar voids, two electrodes and a sensor wetting circuit. Exposure to a fluid on the substrate creates an electrically conductive pathway is formed between the anterior grid and posterior grid through at least one through via, giving rise to a change in an electrical property between the two electrodes, as measured by the sensor wetting circuit, which generates an interrupt signal or alarm.

### CROSS REFERENCE TO RELATED APPLICATION

The Present Application claims priority to U.S. Provisional Patent Application No. 63/749540, filed on Jan. 25, 2025, which is hereby incorporated by reference in its entirety.

### STATEMENT REGARDING FEDERALLY SPONSORED RESEARCH OR DEVELOPMENT

Not Applicable

### BACKGROUND OF THE INVENTION

### Field of the Invention

The present invention generally relates to devices and systems enabling detection of fluids and methods for achieving the same.

### Description of the Related Art

Water leaks often go unnoticed by homeowners, landlords, water utilities, and data center administrators, leading to significant costs for property owners in terms of repairs. The causes of water damage are diverse, ranging from natural disasters, household flooding to faulty plumbing, appliance malfunctions, leaky fixtures, and problems with irrigation systems. Much of the damage can be averted with early warning systems, allowing the homeowner to pursue swift interventions, such as shutting off the facility water supply or the water line to the fixture or appliance, thereby avoiding a costly water loss. Unfortunately, many homeowners fail to recognize the potential risk of water damage to their homes, which can have a profound impact on their largest financial investment. Around 29.4% of all home insurance claims are attributed to water damage and freezing, which is second only to wind and hail damage (34.3% of all claims), causing significant economic hardship to homeowners and insurers alike.

Water damage affects around 14,000 people in the U.S. every single day. 98% of basements in the US will experience some type of water damage during their lifespans. 37% of US homeowners claim to have suffered significant losses from water damage. $2.5B annual cost to insurance companies from water damage and mold remediation in the US. In terms of economic burden on a per capita basis, the average cost of a home water damage insurance claim is $6,965 and often can extend into five figures if the damage is extensive or otherwise not caught early.

Data center operators are evaluating liquid cooling technologies to increase energy efficiency and remove latent heat as processing-intensive computing applications (e.g., AI, LLMs, cryptocurrency transactions) and hardware power requirements continue to grow at an impressive pace. Increased heat generation must be removed for computing hardware to behave reliably and perform properly. Currently, data centers support rack power requirements in excess of 20 kilowatts (kW), but the market is headed to 50 kW or more. As an example, a hyperscale data center might have upward of 40 racks in a cabinet, and over 100 cabinets on a data center floor, requiring an astounding 200 MW of electrical power to operate, mostly dissipated as waste heat. Newer-generation central processing units (CPUs), graphics processing units (GPUs), and neural processing units (NPUs) have higher thermal density properties than previous-generation architectures. In addition, server manufacturers are packing more CPUs, GPUs, and NPUs into each rack to meet the accelerating demand for high-performance computing and AI applications. Passive and active air cooling is now showing its limits; conventional convective air transport is now becoming insufficient to cool high-density racks in an efficient manner. As a result, data center operators are exploring liquid cooling options. Liquid cooling leverages the higher thermal transfer properties of water (or other fluids) to support efficient and cost-effective cooling of high-density racks and can be up to 3000 times more effective than convective transport of air. Despite the obvious benefits afforded by liquid cooling technologies, cooling fluid leaks can cause catastrophic failure, including downtime and destruction of critical, high-cost infrastructure. Accordingly, leak detection is a crucial, preventative measure for data centers.

As human longevity continues to expand, the convergence of aging in place, decentralized healthcare monitoring/remote patient monitoring, and maintaining independence is driving new models of care for elderly populations. Indeed, nearly 90% of seniors want to stay in their own homes as they age. Aging in place has numerous benefits -promoting life satisfaction, a positive quality of life, and self-esteem—all of which are needed to remain happy, healthy, and well into old age. Urinary incontinence is a disease of reduced bladder function with high prevalence in the elderly. Detection of episodes of incontinence, which often occur when asleep, are essential to avoid downstream consequences such as urinary tract infections, skin irritation, and pressure sores.

Prior art methods of achieving leak detection have conventionally involved point probes, which are highly confined in the x-y dimension and can only detect leaks when their position coincides with an area where there is water. Twisted pair wires improve on this method and are able to detect leaks over an extended x- or y-dimension, but not both spatial dimensions simultaneously. Said prior art methods typically make use of a two-terminal detection circuit to detect a leak event by means of a change in an electrical parameter, typically a conductivity value.

Other prior art leak detection methods have included flow rate sensors to measure anomalies in supply pipes. A leak in an otherwise closed system would result in a small, measurable, consistent flow. U.S. Pat. No. 9,940,815 discloses a fluid leak detection alarm system. U.S. Pat. No. 10,420,682 discloses a sensor and arrangement for measuring moisture and the presence of a person on a base.

### BRIEF SUMMARY OF THE INVENTION

The invention aims to address the challenge of timely identification of fluid leaks over large areas when mitigations can be pursued to minimize property damage, economic losses, and reduced productivity.

The invention leverages flexible printed circuit board/flexible electronic technology, in conjunction with through-substrate vias, to facilitate wide-area leak detection.

The technology disclosed herein relates to Internet of Things (IoT) devices.

The invention provides for the ability to sense the presence of fluid or liquid over large areas by means of a generally planar substrate featuring vias, or conduits, that facilitate the migration of fluid or liquid from the anterior surface of the substrate to the posterior surface. A regularly-spaced grid of electrical traces is present on both the anterior and posterior surfaces of the substrate. A two-terminal electrical detection circuit is connected to the electrical traces on both the anterior and posterior surfaces of the substrate to detect a leak event by means of a change in an electrical parameter. In such an event, an alert, alarm, or notification is issued.

Leak detection is conventionally achieved by means of linear detection of fluid leaks over one spatial dimension, say, for example, the x-dimension in the Cartesian coordinate system. There are no effective methods to detect fluid leaks over two spatial dimensions, e.g., the x-and y-dimensions over the Cartesian plane. The present invention extends the state of the art by providing a means for detecting fluid leaks over a generally planar or two-dimensional area. In this fashion, leak detection may be realized under a fluid-using appliance (placed on floor, adhered to the inner surface of a drawer, cabinet or cupboard), under a server rack or storage cabinet, under a cooling distribution unit, under fluid delivery lines/plumbing, or on a mattress or gurney (substrate can be bedding for incontinence detection and comprise a fabric; conductive grid is formed by a conductive thread or yarn).

One aspect of the present invention is a wide-area leak detection system. The system includes a substrate, electrically conducting material deposed on the substrate, through vias on the substrate, electrodes, and a sensor wetting circuit. The substrate has an anterior surface and a posterior surface, and is electrically insulative and generally planar. The electrically conducting material is deposed, in a repeating geometric arrangement, on the anterior surface and posterior surface of the substrate, thereby forming an anterior grid on the anterior surface and a posterior grid on the posterior surface. The anterior grid and posterior grid electrically insulated. The through-substrate vias form a columnar void between the anterior surface and the posterior surface of the substrate. The first electrode is configured to make ohmic contact with the anterior grid and the second electrode is configured to make ohmic contact with the posterior grid. The sensor wetting circuit is in electrical communication with the first electrode and the second electrode. The sensor wetting circuit is configured to measure a change in an electrical property between the first electrode and the second electrode, and is configured to generate an interrupt signal or alarm. Upon exposure to a fluid on the anterior surface or the posterior surface of the substrate, an electrically conductive pathway is formed between the anterior grid and the posterior grid through at least one through substrate via. A change in an electrical property between the first electrode and the second electrode, as measured by the sensor wetting circuit, generates an interrupt signal or alarm.

Another aspect of the present invention is a wide-area leak detection system. The system includes a software application, a base station hub having a wireless transceiver and in communication with a remote server over a network, and an apparatus. The apparatus includes a substrate, electrically conducting material deposed on the substrate, through vias on the substrate, electrodes, and a sensor wetting circuit. The substrate has an anterior surface and a posterior surface, and is electrically insulative and generally planar. The electrically conducting material is deposed, in a repeating geometric arrangement, on the anterior surface and posterior surface of the substrate, thereby forming an anterior grid on the anterior surface and a posterior grid on the posterior surface. The anterior grid and posterior grid electrically insulated. The through-substrate vias form a columnar void between the anterior surface and the posterior surface of the substrate. The first electrode is configured to make ohmic contact with the anterior grid and the second electrode is configured to make ohmic contact with the posterior grid. The sensor wetting circuit is in electrical communication with the first electrode and the second electrode. The sensor wetting circuit includes a microcontroller and a wireless transceiver. The sensor wetting circuit is configured to measure a change in an electrical property between the first electrode and the second electrode, and is configured to generate an interrupt signal or alarm. Upon exposure to a fluid on the anterior surface or the posterior surface of the substrate, an electrically conductive pathway is formed between the anterior grid and the posterior grid through at least one through substrate via. A change in an electrical property between the first electrode and the second electrode, as measured by the sensor wetting circuit, a signal to transmit via the wireless transmitter to the base station hub to the remote server and to the software application to indicate the detection of a leak.

Having briefly described the present invention, the above and further objects, features and advantages thereof will be recognized by those skilled in the pertinent art from the following detailed description of the invention when taken in conjunction with the accompanying drawings.

### BRIEF DESCRIPTION OF THE SEVERAL VIEWS OF THE DRAWINGS

FIG. 1A is an illustration of a generally planar, electrically insulative

substrate featuring a rectangular grid of conductive traces, showing the anterior surface.

FIG. 1B is an illustration of a generally planar, electrically insulative substrate featuring a rectangular grid of conductive traces, showing the posterior surface.

FIG. 2A is an illustration of an alternative embodiment of FIG. 1 wherein the grid is a periodic array of conductive traces, showing the anterior surface.

FIG. 2B is an illustration of an alternative embodiment of FIG. 1 wherein the grid is a periodic array of conductive traces, showing the posterior surface.

FIG. 3 is a block diagram of cross sections of a generally planar, electrically insulative substrate featuring an electrically conductive grid on both anterior and posterior surface of said substrate, showing through-substrate vias..

FIG. 4 is cross section of a wide-area leak detection system.

FIG. 5A is a sensor wetting circuit embedded within a housing, the housing in an engaged state.

FIG. 5B is a sensor wetting circuit embedded within a housing, the housing maintained in a closed state.

FIG. 6 is a block diagram of a sensor wetting circuit.

FIG. 7 is a block diagram of a wide-area leak detection system.

FIG. 8 is a flow chart for a method for detecting leaks over wide areas.

FIG. 9 is a block diagram of a sensor wetting circuit.

FIG. 10 is a block diagram of a sensor wetting circuit.

FIG. 11 is a block diagram of a cross section of a generally planar, electrically insulative substrate showing a through-substrate via.

FIG. 12 is a block diagram of a cross section of a generally planar, electrically insulative substrate showing a through-substrate via with liquid.

FIG. 13 is a block diagram of the system's architecture.

FIG. 14 is an illustration of a generally planar, electrically insulative substrate featuring a rectangular grid of conductive traces, and a sensor wetting circuit (housing).

FIG. 15 is a block diagram of a cross section of a generally planar, electrically insulative substrate for capacitive sensing.

FIG. 16 is a block diagram of a cross section of a generally planar, electrically insulative substrate for capacitive sensing.

FIG. 17 is a graph of electrochemical waveforms applied between anterior and posterior electrodes for chronoamperometry.

FIG. 18 is a graph of electrochemical waveforms applied between anterior and posterior electrodes for chronocoulometry.

FIG. 19 is a graph of electrochemical waveforms applied between anterior and posterior electrodes for electrochemical impedance spectroscopy.

FIG. 20 is a plot of potential vs time.

FIG. 21 is a chronoamperometry plot for deionized water.

FIG. 22 is a chronoamperometry plot for propylene glycol.

FIG. 23 is a chronoamperometry plot for ethylene glycol.

FIG. 24 is a chronoamperometry plot for mineral oil.

FIG. 25 is a chronoamperometry plot for TMC-328/Flourinert.

### DETAILED DESCRIPTION OF THE INVENTION

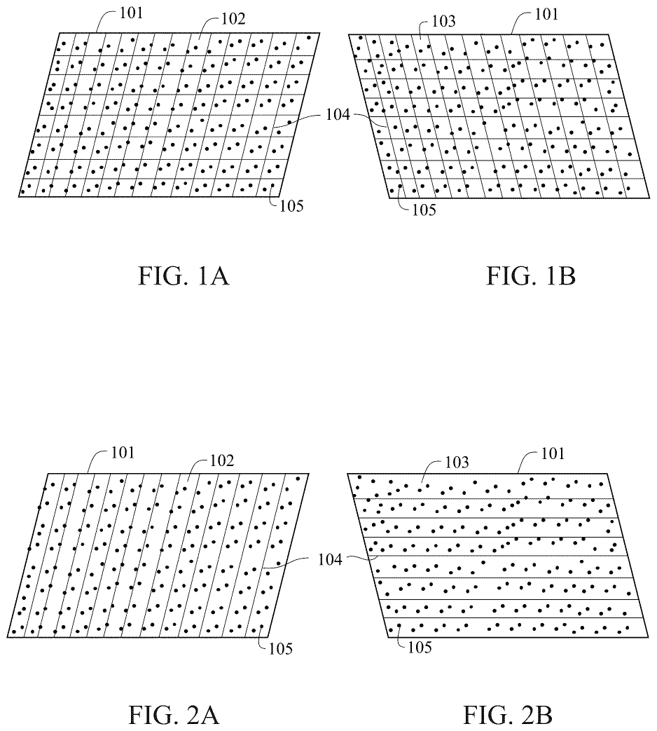

To address the limitations of conventional 1-dimensional leak detection technology, FIGS. 1A-1B illustrates a generally planar, electrically insulative substrate 101 having an anterior surface 102 and a posterior surface 103. The generally planar, electrically insulative substrate 101 features a rectangular grid, a periodic array (FIGS. 2A-2B), or other suitable geometric arrangement of electrically conductive traces 104 on both anterior 102 and posterior surfaces 103 of the substrate. The anterior and posterior electrically conductive grids are insulated from one another by means of the substrate 101 to prevent current conduction between the two trace regions.

The electrically conducting material 104 includes nickel, silver, copper, carbon, gold, platinum, palladium, tin, aluminum, an alloy of two or more metals, a metal salt, a conducting oxide, or conducting polymer.

The repeating geometric arrangement can be rectangular, polar, triangular, hexagonal, or polygonal in nature.

The anterior grid is arranged such that its position is translated one-half pitch in the x- and y-coordinate planes with respect to the posterior grid. Alternatively, the anterior grid is arranged such that its position is translated one-half pitch in the r- and θ-coordinate planes with respect to the posterior grid.

The anterior grid can alternatively be arranged such that its position is overlapping in the x- and y-coordinate planes with respect to the posterior grid. Further, alternatively, the anterior grid is arranged such that its position is overlapping in the r- and θ-coordinate planes with respect to the posterior grid.

The anterior grid and posterior grid are deposited using thick-film fabrication techniques such as screen printing, pad printing, inkjet printing, gravure, roll-to-roll printing, electroplating, laminating, or sputtering.

Through-substrate vias 105 are between 10 microns and 10,000 microns in diameter, and preferably between 100 microns and 1,000 microns in diameter.

In certain embodiments, the through-substrate via 105 is formed after the deposition of the anterior electrode, the posterior electrode, or both the anterior and posterior electrodes. In certain embodiments, the through-substrate via 105 is formed by laser ablation, hole punching, kiss-cutting, rotary die, heat-staking, a dry etching process, a wet etching process, a chemical etching process, a plasma etching process, or photolithography.

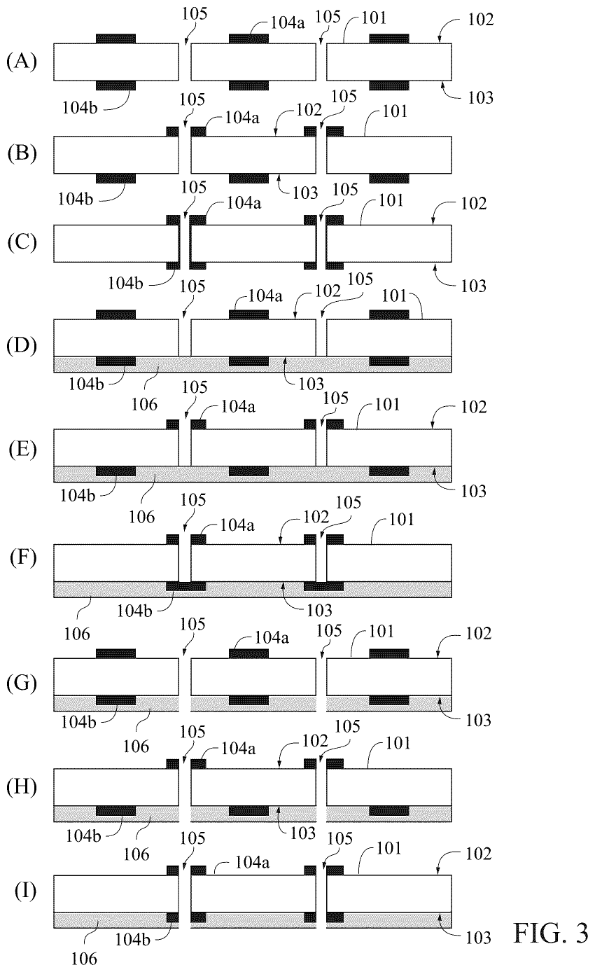

The through-substrate vias 105 provide columnar voids between the anterior 102 and posterior surfaces 103 of the substrate 101 and enable fluid to traverse from the anterior surface 102 to the posterior surface 103 of said substrate 101, hence providing an electrically conductive pathway between the anterior grid and posterior grid. FIG. 3 provides a bisected profile view of several configurations of the through-substrate vias 105.

In reference to FIG. 3, the through-substrate vias 105 are either: interleaved between the anterior 104a and posterior 104b grids (e.g., regularly arranged at the grid's half-pitch, (A), (D), (G) ); bisect the anterior grid 104a while interleaved between the posterior grid 104b (B), (E), (H); bisect both the anterior 104a and posterior 104b grids (C), (F), (I).

Optionally, an adhesive 106 may be placed on the posterior surface 103 of the generally planar, electrically insulative substrate 101, FIG. 3 (D-I). Through-substrate vias may 105 either come to termination at the posterior surface 103 of the generally planar, electrically insulative substrate 101, FIG. 3 (D-F), or further extend through the adhesive 106, FIG. 3 (G-I).

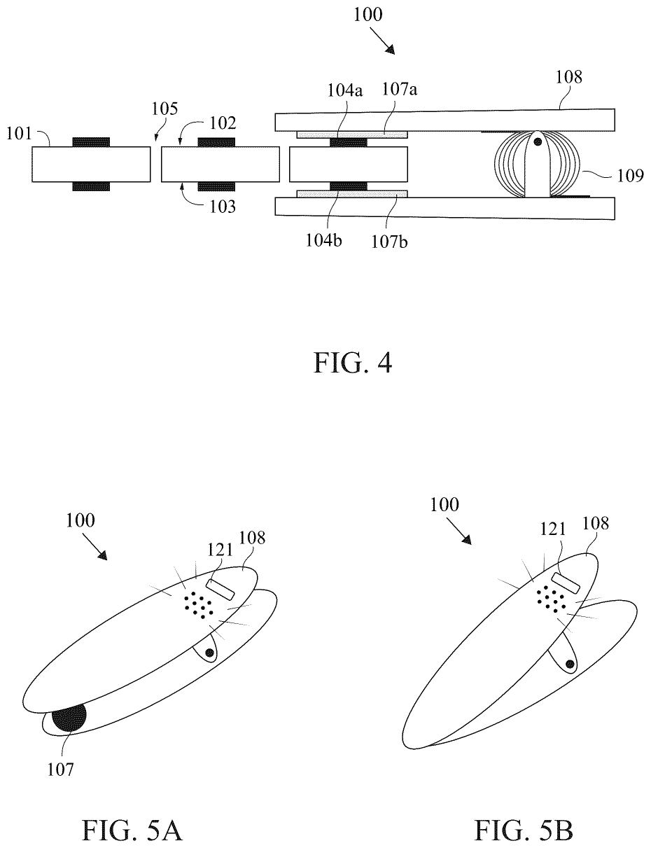

A contingent of two electrodes 107, preferably comprised of a metal, with the first electrode 107a configured to make ohmic contact with the anterior grid 104a and the second electrode 107b configured to make ohmic contact with the posterior grid 104b are shown in FIG. 4. The two electrodes 107 are mounted or otherwise retained in a housing 108 and are placed in ohmic contact with the opposing surfaces of the planar substrate 101 by means of a torsion spring 109 applying compressive force to the planar substrate 101. The housing 108 contains a sensor wetting circuit 100 embedded within. The housing 108 contains, among other user-interfaceable elements, LED illumination 121 to indicate device status and a buzzer to provide an audible alarm upon detection of an interrupt signal, shown in FIGS. 5A-5B. Optionally, the housing 108 may contain a display, other user interface (UI), or user-selectable controls, such as buttons. The sensor wetting circuit 100 is configured to measure a change in electrical property between the two said electrodes 107, coinciding with the detection of a fluid.

In certain embodiments, the anterior electrode 107a is selected from one of the following materials: carbon, nickel, tin, gold, platinum, palladium, poly(3,4-ethylenedioxythiophene) polystyrene sulfonate, or poly(pyrrole). In certain embodiments, the posterior electrode 107b is selected from one of the following materials: carbon, nickel, tin, gold, platinum, palladium, poly(3,4-ethylenedioxythiophene) polystyrene sulfonate, or poly(pyrrole), silver, or silver-chloride,

In certain embodiments, a two-terminal sensing mechanism is established comprising an anterior (or working) electrode and a posterior (or reference) electrode. In other embodiments, a three-terminal sensing mechanism is established comprising an anterior (or working) electrode, a posterior (or counter) electrode, and a reference electrode (which may be located on at least one of the anterior surface or posterior surface of the generally planar substrate).

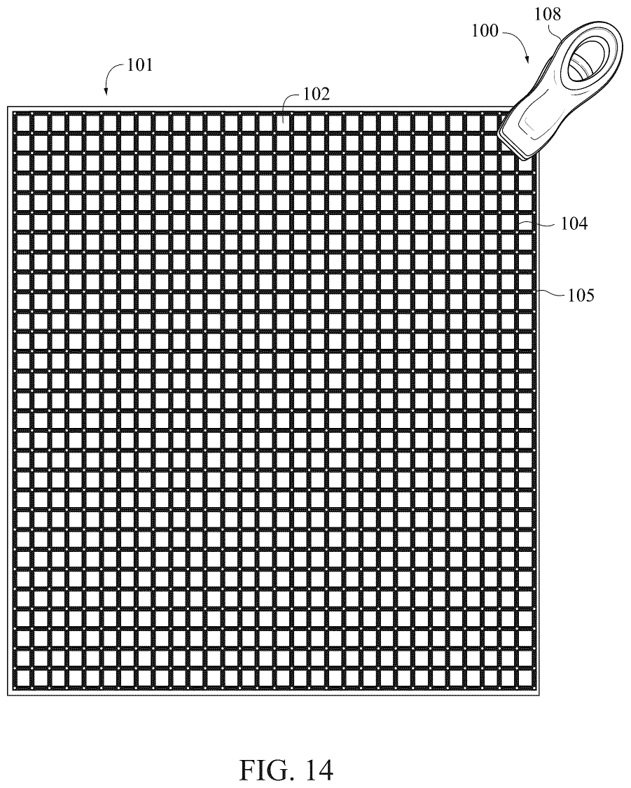

FIG. 5A shows a sensor wetting circuit 100 embedded within a housing 108, the housing 108 engaged to show one of two electrodes 107 located at the distal end of one armature of the housing 108. FIG. 5B shows the housing 108 maintained in its closed state, also shown in FIG. 14.

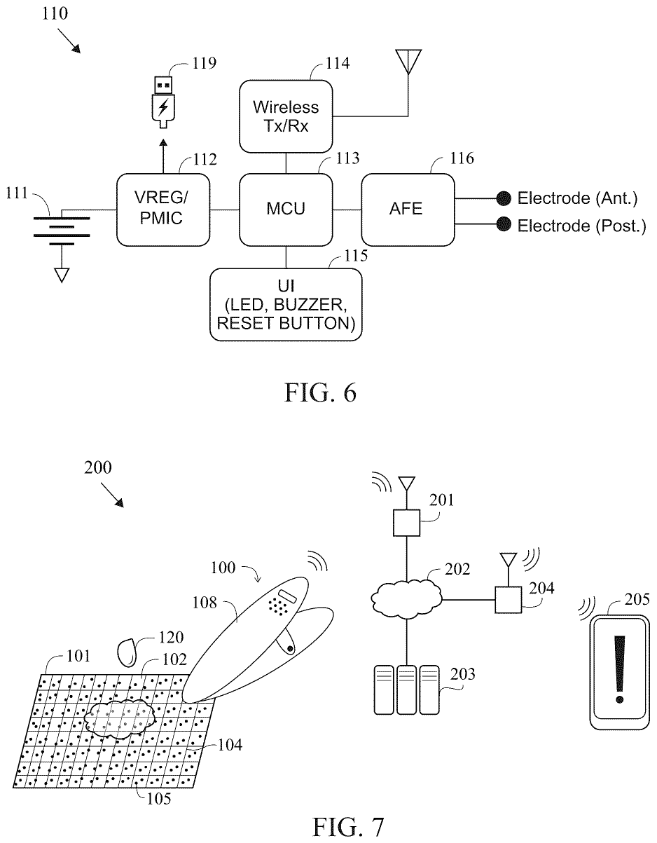

FIG. 6 illustrates a sensor wetting circuit block diagram 110 outlining the following components (not necessarily exhaustive or otherwise entirely required for operation): a primary or secondary battery 111, a voltage regulator (VREG) or power management integrated circuit (PMIC) 112 capable of maintaining low power operation and/or interfacing with a USB-based battery charger, a microcontroller (MCU) 113 featuring a processor and an executable memory, a wireless transmitter/receiver (Tx/Rx) 114 operating using an established wireless communication technique (i.e., Bluetooth, WiFi, Zigbee, LoRaWAN, Thread, z-Wave, NB-IoT, LTE Cat-M1, cellular), a user-interface (UI) 115 for presenting the user with a status indication (i.e., LED, buzzer, reset button), and an analog front end (AFE) 116 capable of measuring a change in an electrical property between two electrodes, as measured by said sensor wetting circuit.

An AFE 116 can comprise discrete elements (e.g., transistor, diode, resistor, capacitor, inductor), lumped elements (e.g., operational amplifier, wheatstone bridge, integrator, differentiator, comparator, buffer, pull-up, pull-down, general-purpose input/output pin, voltage divider), monolithically-integrated elements (e.g., short circuit detector, continuity detector, potentiostat, galvanostat, impedance analyzer, electrochemical analyzer, electrometer, source-measureme unit) or a combination thereof.

FIG. 7 and FIG. 14 show a preferred embodiment of a wide-area leak detection system 200 comprising of: a generally planar substrate 101 having an anterior surface 102 and a posterior surface 103 (shown in FIGS. 1A-2B), the substrate 101 being electrically insulative; an electrically conducting material 104 in a repeating geometric arrangement on the anterior surface 102 and posterior surface 103 of the generally planar substrate 101, thereby forming an anterior grid and a posterior grid, respectively, both electrically insulated; through-substrate vias 105 forming a columnar void between the anterior surface 102 and the posterior surface 103 of the generally planar substrate 101; two electrodes 107, with the first electrode 107a configured to make ohmic contact with the anterior grid and the second electrode 107b configured to make ohmic contact with the posterior grid (shown in FIG. 4); a sensor wetting circuit 100 in electrical communication with the two electrodes 107 and configured to measure a change in an electrical property between the two electrodes 107 and to generate an interrupt signal or alarm.

Upon exposure to a fluid 120 on a surface of the planar substrate 101, an electrically conductive pathway is formed between the anterior grid and posterior grid through at least one through-substrate via 105, thus giving rise to a change in an electrical property between the two electrodes 107.

The electrically conductive pathway has a resistance between 0.1 ohm and 1 peta-ohm (1E15 ohm), and preferably between 10 ohms and 10 tera-ohm (1E12 ohm). The electrical property is a current, a resistance, a voltage, an impedance, a capacitance, an inductance, or a dielectric value.

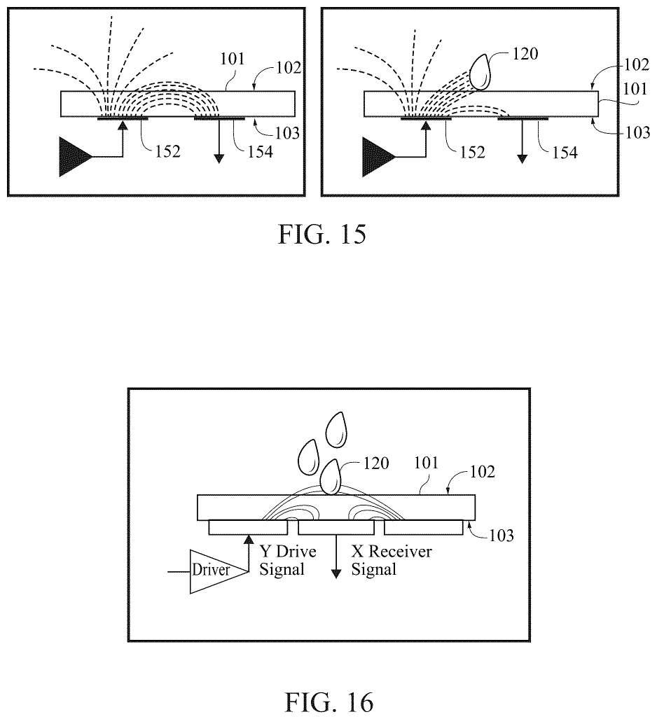

In an alternative embodiment, capacitive sensing, as shown in FIGS. 15-16, is employed to ascertain the presence of a fluid 120. In such embodiments, the presence of a fluid 120 will cause a change in the dielectric properties or otherwise interact with the electric field between a drive electrode 152 and sense electrode 154 or an anterior electrode and a posterior electrode. The drive 152 and sense 154 electrodes may be placed on either the anterior 102 or posterior 103 surfaces of the generally planar substrate 101. In such embodiments, a capacitance-to-digital converter 146 is employed to convert a measured capacitance value to a digital value reflective of the capacitance measured.

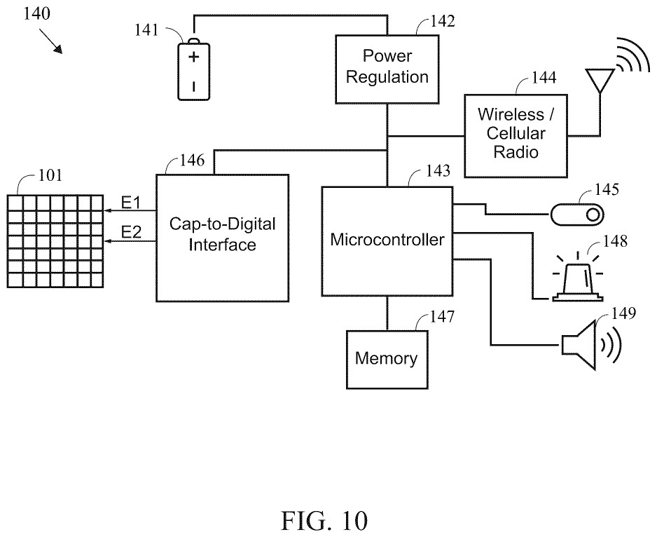

A sensor wetting circuit block diagram 140 with a capacitance-to-digital converter 146 is shown in FIG. 10. The circuit 140 includes the following components: a battery 141, a power regulator 142, a microcontroller 143, memory 147, a wireless Tx/Rx 144 operating using an established wireless communication technique (i.e., Bluetooth, WiFi, Zigbee, LoRaWAN, Thread, z-Wave, NB-IoT, LTE Cat-M 1, cellular), a UI/button 145, a light/display 148, and a speaker/buzzer 149.

In reference to FIG. 7, upon exposure to a fluid or liquid 120 at a planar substrate 101, a wireless signal is relayed to a local wireless hub/base station/cellular station device 201, which then transmits this signal over a packet-switched network 202 (e.g., the Internet) to a Cloud service 203. An application installed in the user's smartphone, smartwatch, tablet, computer, or other Internet-connected device 205 also is connected to said Cloud service 203 by means of a local wireless hub/base station/cellular station/network switch device 204 in the user's vicinity. An alert or alarm is presented on a software/mobile application installed on the user's smartphone, smartwatch, tablet, computer, or other Internet-connected device 205 indicating a leak has been detected.

Optionally, the software/mobile application queries the user to take a corrective action (e.g., remote valve shutoff, re-circulating pump shutoff, etc.). Optionally, the software/mobile application automatically instigates a valve connected to a packet-switched network to move into a closed position to attest the further flow of a fluid.

The system preferably uses a low power microcontroller and a WiFi/BLE/LoRa radio.

A fluid 120 may comprise any liquid-phase material, including aqueous and non-aqueous media.

In one exemplary embodiment, the wide-area leak detection system is employed to detect the presence of one of the following fluids: tap water, filtered water, purified water, distilled water, deionized water, mineral oil, silicone oil, propylene glycol, ethylene glycol, a water/glycol mixture, a perfluorocarbon liquid, a hydrocarbon liquid, a dielectric liquid, or a non-conductive liquid.

In one exemplary embodiment, the wide-area leak detection system is employed to detect the presence of a fluid with one of the conductivity ranges:
between 1 μS/cm and 1E-02 μS/cm, between 1E-02 μS/cm and 1E-04 μS/cm, between 1E-04 μS/cm and 1E-06 μS/cm, between 1E-06 μS/cm and 1E-08 μS/cm, and between 1E-08 μS/cm and 1E-10 μS/cm.

For fluids that are conducting, moderately conducting, or weakly conducting, a traditional conductometric measurement may be pursued to assess the presence of a fluid. In this case, a finite current value or resistance value is measured, which is indicative of the presence of a fluid. The presence of a fluid may also complete a sensing circuit, allowing the passage of a finite (and measurable) amount of electrical current.

In alternative embodiments, wherein the fluid is non-conductive (e.g., a fluorocarbon), a change in capacitance value between the anterior and posterior grids may be measured by the sensor wetting circuit.

In alternative embodiments, signal relay can be performed over a wired system.

The interrupt signal or alarm is audible, visual, transmitted to a remote device by a conductor, or is transmitted to a remote device by a wireless radio. The interrupt signal is incident upon at least one of a processor, illumination source, display, vibrator, buzzer, speaker, an electrical interface, an electrical data bus, and a wireless radio.

In certain embodiments the generally planar substrate 101 comprises a polymer film, polystyrene, polyimide, mylar, polyurethane, polyethylene, polypropylene, polyester, polyvinyl chloride, polyethylene terephthalate, polytetrafluoroethylene, polycarbonate, polymethyl methacrylate, acrylonitrile-butadiene-styrene, cellulose acetate, Kapton, Nylon, or plastic.

The generally planar substrate 101, which may be coated with a pressure-sensitive adhesive, a double-sided adhesive, a laminated adhesive, an adhesive film, or a chemical adhesive 106, may be adhered to a releasable liner material. The releasable liner material may comprise a sheet or film of plastic material configured to protect the generally planar substrate 101 from unintended adhesion prior to placement in the desired location.

The generally planar substrate 101, including the adhered releasable liner material, may be furnished to the user as a roll or in pre-cut sheets. Optionally, the user can cut a desired region of generally planar substrate from said roll or pre-cut sheets to provide coverage over a desired region to facilitate detection of a fluid over the extent of said region. The user is instructed to remove the releasable liner prior to placement in the desired location. Following placement, the generally planar substrate is adhered to a desired surface or region. The user may notate the location of the generally planar substrate on a computer-, mobile-, or smartphone-based application.

In one exemplary embodiment, the wide-area leak detection system is located in at least one of the following locations: underneath the cooling distribution plumbing, underneath the cooling distribution unit, underneath a rackmount server, underneath a rackmount server cabinet, underneath a graphics processing unit, underneath a central processing unit, underneath a neural processing unit, underneath a plenum, and underneath a raised floor.

In another exemplary embodiment, the wide-area leak detection system is located on the bottom surface of the interior of a drawer, on the bottom surface of the interior of a cabinet, underneath plumbing, underneath a water line, underneath a sewage line, underneath a faucet, underneath a spigot, underneath a coupler, or underneath a drain.

Additional embodiments include use of the wide-area leak detection system under a sink, household water-using appliance (i.e., dishwasher, clothes washer, water heater, refrigerator), underneath a cabinet, applied as a lining in a drawer or cupboard, by a toilet, under or between individual server racks (such as those that use liquid cooling), or within a refrigerator (placed on a refrigerator shelf to detect spills or leaks and notify which tray, shelf, drawer leak has occurred).

The wide-area leak detection system may be used in construction, including within or otherwise on foundations, within/under subfloor, in basement/cellar, behind walls, or underneath flooring.

In certain embodiments, the wide-area leak detection system is intended to identify fluid leaks over a surface area that ranges: between 10 cm² and 100 cm²; between 100 cm² and 1 m²; between 1 m² and 10 m²; between 10 m² and 100 m²; between 100 m² and 1000 m²; and between 1000 m² and 10,000 m².

In certain embodiments, the wide-area leak detection system uses location services to identify location of placement. Said location services may comprise: a GPS radio, a Bluetooth Low Energy Beacon, Bluetooth Low Energy Channel Sounding, Bluetooth Angle of Arrival/Angle of Departure, RSSI-based triangulation or time difference of arrival, an indoor positioning system, or a real-time location system.

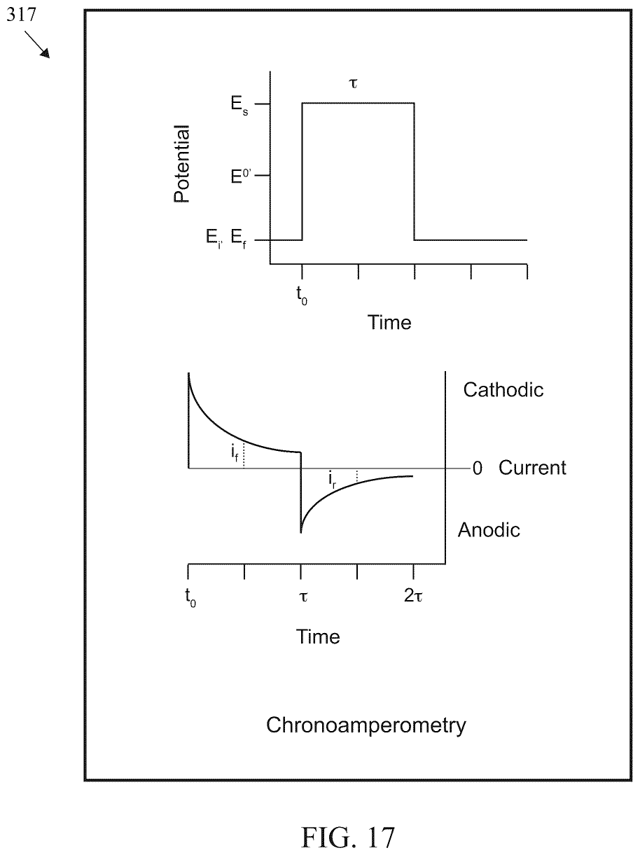

In one exemplary embodiment, chronoamperometry is used to detect the presence of a fluid. As shown in the graphs 317 of FIG. 17, a potential is stepped to a high value, held for a first set period of time, then stepped down to a low value and held for a second set period of time. The high value may be between 0.2 and 1.5 V applied between the anterior and posterior electrodes. The first set period of time may be between 1 ms and 10,000 ms. The low value may be between −0.5 and 0.5 V applied between the anterior and posterior electrodes. The second set period of time may be between 1 ms and 10,000 ms. This routine may be performed once every one second, once every two seconds, once every five seconds, once every ten seconds, once every fifteen seconds, twice a minute, once a minute, once every two minutes, once every five minutes, once every ten minutes, once every fifteen minutes, twice an hour, or once an hour. This routine may also be reversed, wherein the potential is first stepped to a low value, held for a first set period of time, and then stepped to a high value, and held for a second set period of time. The system may enter a low power state when said chronoamperometry routine is not performed.

In chronoamperometry, the transient current measured immediately following any potential step may indicate a non-Faradaic response, corresponding to the charging or discharging of the double layer. It may also indicate the formation of a Stern layer or diffuse layer.

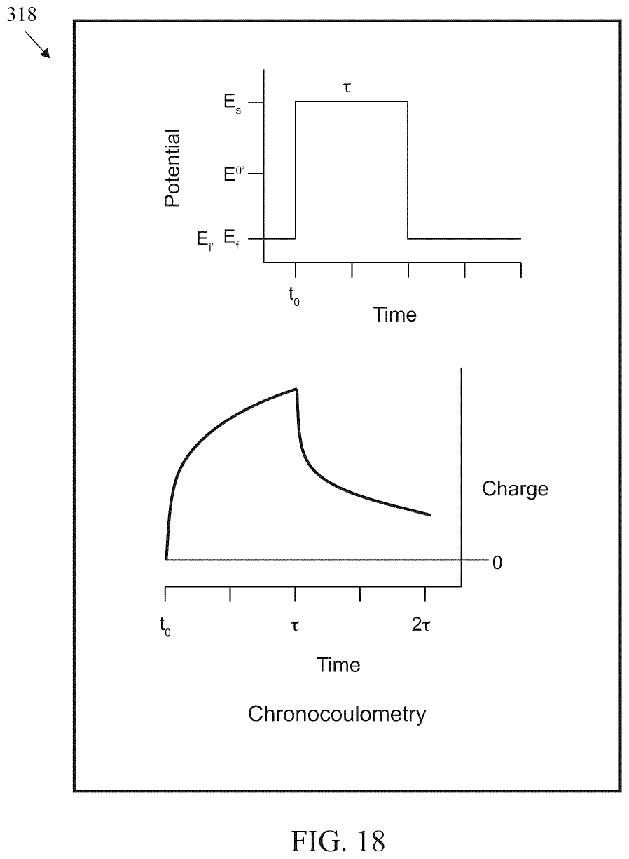

In another exemplary embodiment, chronocoulometry is used to detect the presence of a fluid. As shown in the graphs 318 of FIG. 18, the same measurement routine as described for chronoamperometry may be invoked, but measured current is integrated over time and compared against a reference value to ascertain if a fluid is present.

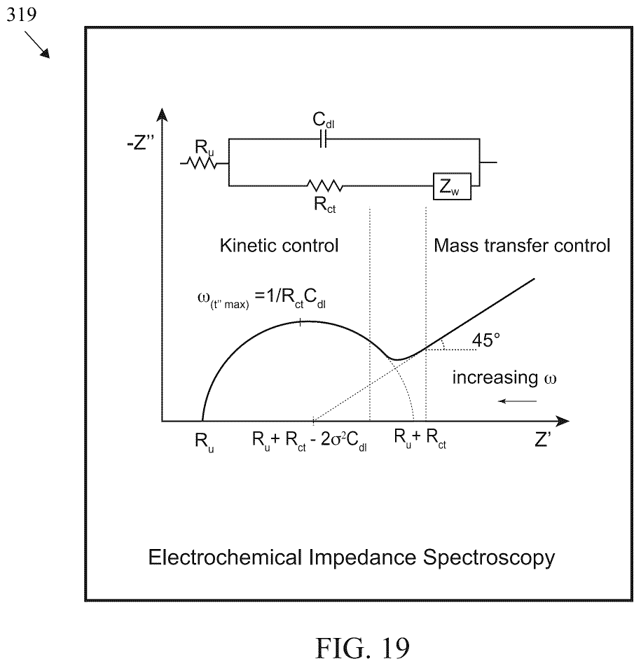

In yet another exemplary embodiment, electrochemical impedance spectroscopy is used to detect the presence of a fluid. As shown in the graph 319 of FIG. 19, a DC potential is stepped to a desired value and a small AC sinusoid with a specified amplitude is applied to the DC potential. The sinusoid is synthesized across a plurality of frequencies, which may be between 1 μHz and 1 MHz, and the amplitude and phase response is measured with a frequency response analyzer. The amplitude and phase response, or derived real and imaginary components of the impedance, are compared against a reference value to ascertain the presence of a fluid.

In yet other embodiments, electrochemical impedance spectroscopy may be used to determine the extent and severity of a leak or to identify new leaks. It may also be used to determine if corrosion is occurring or if a certain/new chemical species is found within the leaking fluid.

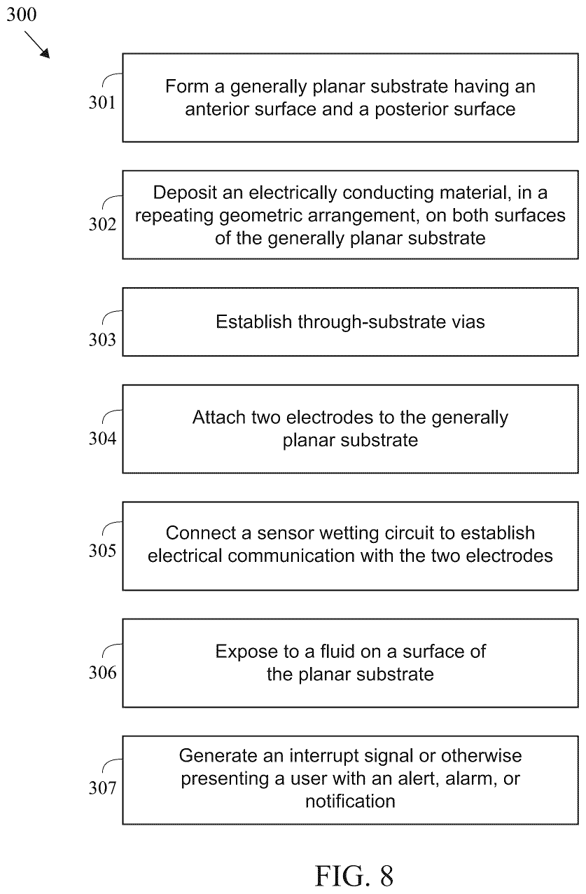

A flow chart 300, shown in FIG. 8, for a method for leak detection begins with forming a generally planar substrate having an anterior surface and a posterior surface, which forms an electrically insulative surface that defines the area covered for leak detection 301.

Next, the method includes depositing an electrically conducting material, in a repeating geometric arrangement, on the anterior surface and posterior surface of said generally planar substrate, which forms an anterior grid and a posterior grid, respectively, with said anterior grid and posterior grid electrically insulated 302.

The method also includes establishing through-substrate vias, which forms a columnar void between the anterior surface and the posterior surface of the said generally planar substrate 303.

The method also includes attaching two electrodes to the said generally planar substrate 304. The first electrode is configured to make ohmic contact with the anterior grid and the second electrode is configured to make ohmic contact with the posterior grid.

The method also includes connecting a sensor wetting circuit to establish electrical communication with said two electrodes, which measures a change in an electrical property between the two electrodes and generate an interrupt signal or alarm 305.

The method also includes exposure to a fluid on a surface of said planar substrate, which forms an electrically conductive pathway between the anterior grid and posterior grid through at least one through substrate via, thus giving rise to a change in an electrical property between the said two electrodes, as measured by said sensor wetting circuit 306.

The method also includes generating an interrupt signal or otherwise presenting a user with an alert, alarm, or notification, which elicits an autonomous or user-defined action to mitigate the presence of fluid 307.

A fluid is an input for the system or method and an interrupt signal or alarm is the output.

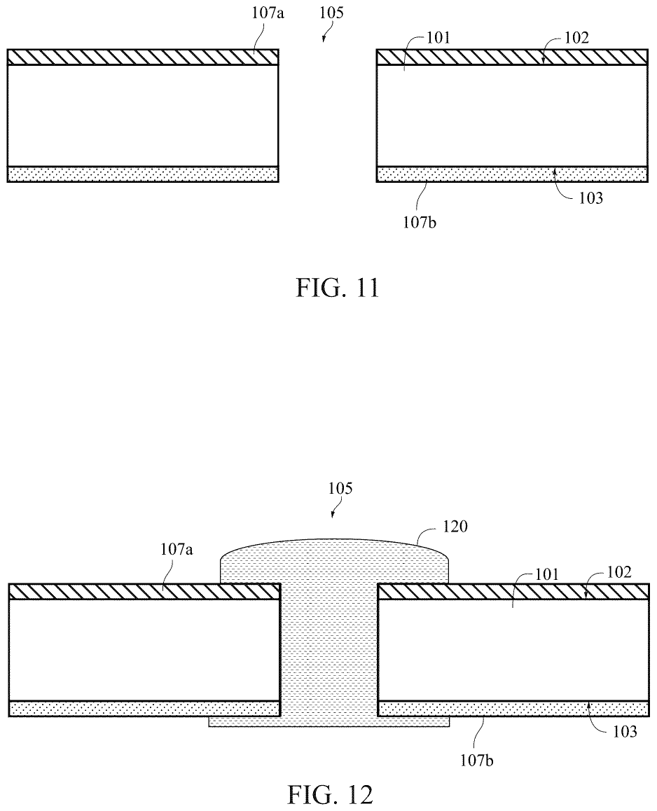

FIGS. 11-12 show an embodiment for leak continuity sensing. Shown is a cross section of a wide-area leak-sensing film: the substrate 101 with an anterior surface 102 and a posterior surface 103, a through-substrate via 105, an anterior electrode 107a, and a posterior electrode 107b. When a liquid 120 traverses from the anterior surface 102 to the posterior surface 103 changes in electrical properties (resistance or capacitance) is sensed.

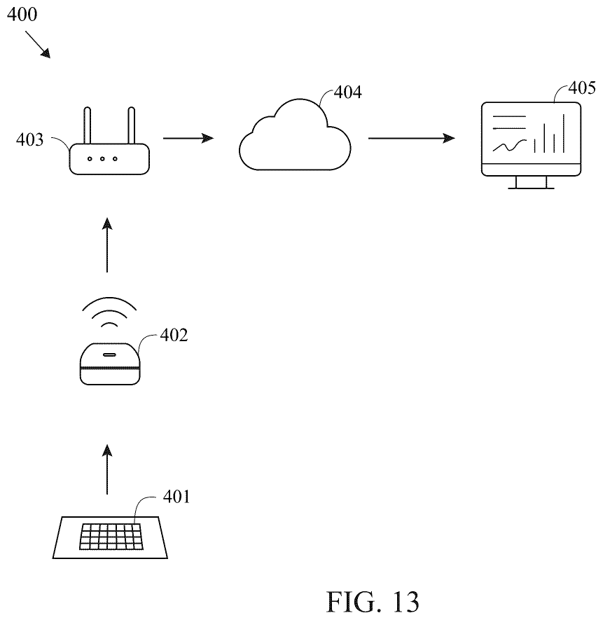

FIG. 13 is a block diagram 400 of the system's architecture, which includes a printed sensor film 401, a wireless node 402, a gateway 403, cloud analytics 404, and a dashboard 405. Advanced algorithms analyze sensor data to detect complex patterns that humans might miss. AI predicts potential failures early, enabling proactive maintenance and reducing downtime. An intelligence engine responds dynamically to changing conditions in data centers. API integration with BMS/DCIM (Building Management System/Data Center Infrastructure Management) may be one possible embodiment.

In certain embodiments, the wireless node 402 comprises a WiFi radio, a Bluetooth Low Energy radio, a LoRa radio, a Zigbee radio, a Thread radio, a z-Wave radio, an NFC radio, an RFID radio, an NB-IoT radio, an LTE-M radio, a cellular radio, or a satellite radio.

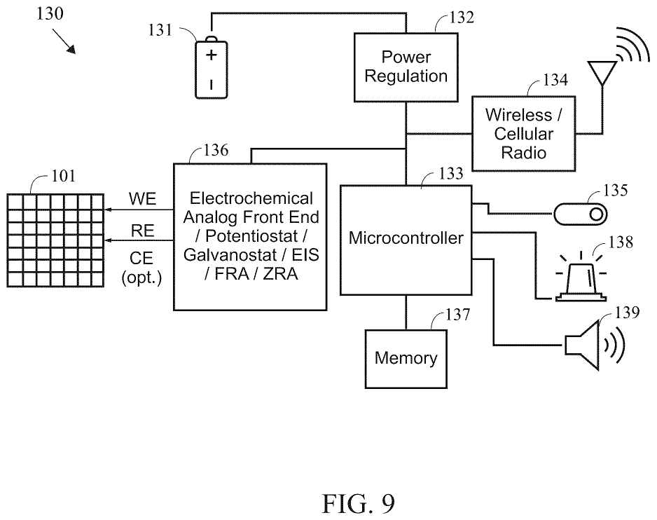

In certain embodiments, the wireless node 402 comprises a sensor wetting circuit 130, shown in FIG. 9. The sensor wetting circuit 130 may contain an electrochemical analyzer, an electrochemical analog front end, a potentiostat, a galvanostat, a frequency response analyzer, a zero-resistance ammeter, a picoammeter, a femtoammeter, an electrometer, or a source-measure unit 136. The circuit also 130 includes the following components (not necessarily exhaustive or otherwise entirely required for operation): a primary or secondary battery 131, a power regulator 132, a microcontroller 133, memory 137, a wireless Tx/Rx 134 operating using an established wireless communication technique (i.e., Bluetooth, WiFi, Zigbee, LoRa, Thread, z-Wave, NB-IoT, LTE Cat-M1, cellular), a UI/button 135, a light/display 138, and a speaker/buzzer 139.

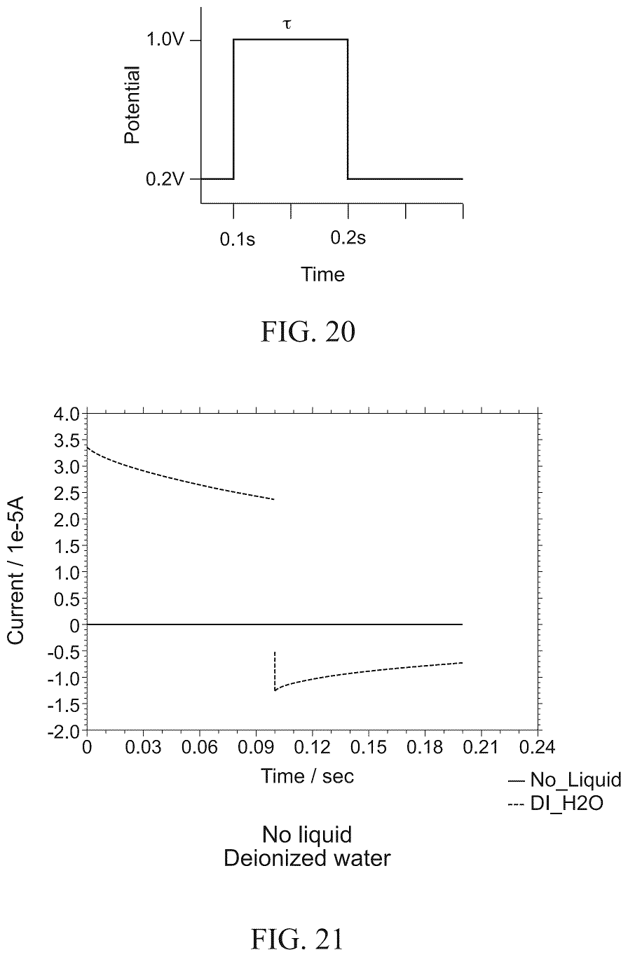

In FIG. 20, a potential is stepped to a high value, held for a first set period of time, then stepped down to a low value and held for a second set period of time, as described for FIG. 17.

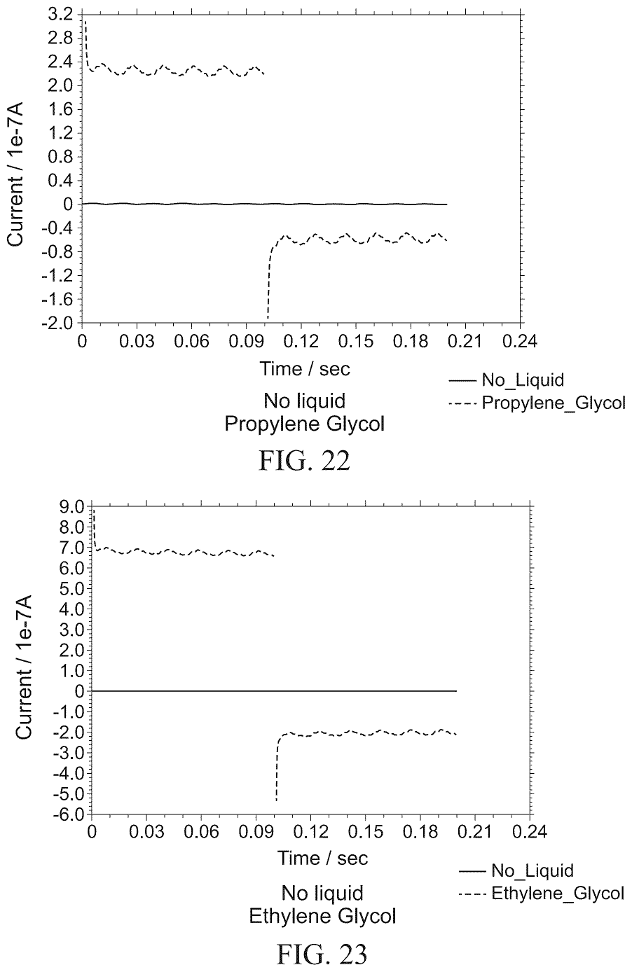

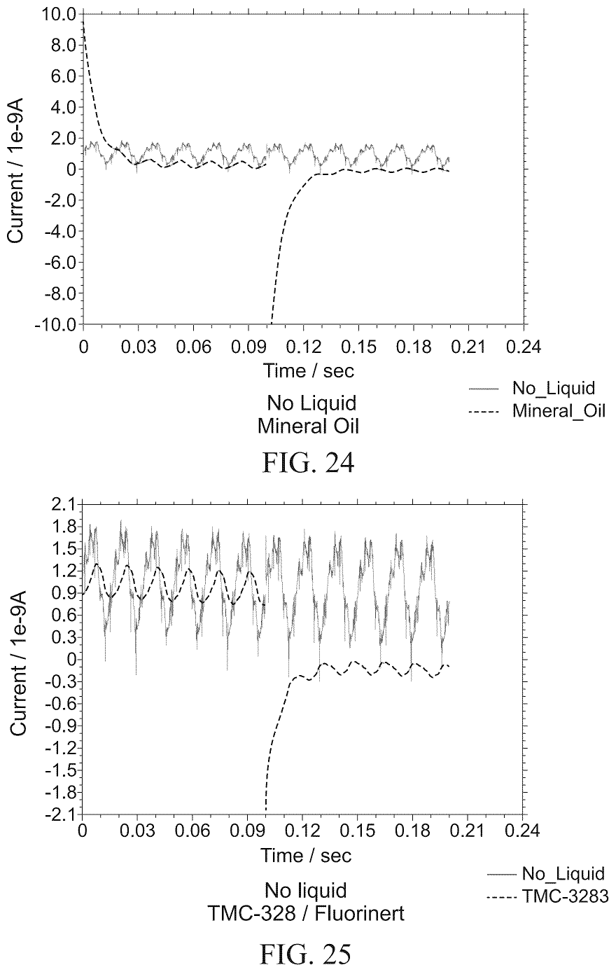

FIGS. 21-25 are chronoamperometry plots for deionized water, propylene glycol, ethylene glycol, mineral oil, and TMC-328/Flourinert, respectively.

From the foregoing it is believed that those skilled in the pertinent art will recognize the meritorious advancement of this invention and will readily understand that while the present invention has been described in association with a preferred embodiment thereof, and other embodiments illustrated in the accompanying drawings, numerous changes modification and substitutions of equivalents may be made therein without departing from the spirit and scope of this invention which is intended to be unlimited by the foregoing except as may appear in the following appended claim. Therefore, the embodiments of the invention in which an exclusive property or privilege is claimed are defined in the following appended claims.

I claim as my invention the following:

1. A wide-area leak detection system comprising:
a substrate having an anterior surface and a posterior surface, said substrate electrically insulative and generally planar;
an electrically conducting material deposed, in a repeating geometric arrangement, on the anterior surface and posterior surface of said substrate, thereby forming an anterior grid on the anterior surface and a posterior grid on the posterior surface, wherein said anterior grid and posterior grid electrically insulated;
a plurality of through-substrate vias forming a columnar void between the anterior surface and the posterior surface of said substrate;
a first electrode configured to make ohmic contact with the anterior grid and a second electrode configured to make ohmic contact with the posterior grid; and
a sensor wetting circuit in electrical communication with said first electrode and said second electrode, the sensor wetting circuit configured to measure a change in an electrical property between said first electrode and the second electrode, and configured to generate an interrupt signal or alarm;
wherein upon exposure to a fluid on the anterior surface or the posterior surface of said substrate, an electrically conductive pathway is formed between the anterior grid and the posterior grid through at least one through substrate via of the plurality of through substrate vias, wherein a change in an electrical property between the said first electrode and said second electrode, as measured by said sensor wetting circuit, generates an interrupt signal or alarm.

2. The device of claim 1, wherein said substrate is a polymer film composed of a polystyrene, a polyimide, a mylar, a polyurethane, a polyethylene, a polypropylene, a polyester, a polyvinyl chloride, a polyethylene terephthalate, a polytetrafluoroethylene, a polycarbonate, a polymethyl methacrylate, an acrylonitrile-butadiene-styrene, a cellulose acetate, a Kapton, or a nylon.

3. The device of claim 1, wherein said substrate is coated with a pressure-sensitive adhesive, a double-sided adhesive, a laminated adhesive, an adhesive film, or a chemical adhesive.

4. The device of claim 1, wherein said electrically conducting material includes nickel, silver, copper, carbon, gold, platinum, palladium, tin, aluminum, an alloy of two or more metals, a metal salt, a conducting oxide, or conducting polymer.

5. The device of claim 1, wherein said repeating geometric arrangement is rectangular, polar, triangular, hexagonal, or polygonal.

6. The device of claim 1, wherein a position of said anterior grid is translated one-half pitch in the x- and y-coordinate planes with respect to the posterior grid.

7. The device of claim 1, wherein a position of said anterior grid is translated one-half pitch in the r- and θ-coordinate planes with respect to the posterior grid.

8. The device of claim 1, wherein a position of said anterior grid is overlapping in the x- and y-coordinate planes with respect to the posterior grid.

9. The device of claim 1, wherein a position of said anterior grid is overlapping in the r- and θ-coordinate planes with respect to the posterior grid.

10. The device of claim 1, wherein each of said plurality of through-substrate vias is between 10 microns and 10,000 microns in diameter.

11. The device of claim 1, wherein said sensor wetting circuit comprises at least one of a short circuit detector, an electrochemical analog front end, a potentiostat, a galvanostat, an impedance analyzer, a frequency response analyzer, a femtoammeter, a picoammeter, an electrometer, a source/measure unit, a wheatstone bridge, an integrator, a differentiator, a comparator, a buffer, an operational amplifier, a transistor, a pull-up, a pull-down, a general-purpose input/output pin, or a voltage divider.

12. The device of claim 1, wherein said sensor wetting circuit is connected to at least one of a processor, a display, and a wireless radio.

13. The device of claim 1, wherein said electrical property is a current, a resistance, a voltage, an impedance, a capacitance, or a dielectric value.

14. The device of claim 1, wherein said electrically conductive pathway has a resistance between 0.1 ohm and 1 peta-ohm, and preferably between 1 ohm and 1 tera-ohm.

15. The device of claim 12, wherein said interrupt signal or alarm is audible, visual, transmitted to a remote device by a conductor, or is transmitted to remote device by said wireless radio.

16. The device of claim 1, wherein said interrupt signal is incident upon at least one of a processor, illumination source, display, vibrator, buzzer, speaker, an electrical interface, an electrical data bus, and a wireless radio.

17. A wide-area leak detection system comprising:
a software application;
a base station hub having a wireless transceiver and in communication with a remote server over a network;
an apparatus comprising
a substrate having an anterior surface and a posterior surface, said substrate electrically insulative and generally planar,
an electrically conducting material deposed, in a repeating geometric arrangement, on the anterior surface and posterior surface of said substrate, thereby forming an anterior grid on the anterior surface and a posterior grid on the posterior surface, wherein said anterior grid and posterior grid electrically insulated,
a plurality of through-substrate vias forming a columnar void between the anterior surface and the posterior surface of said substrate,
a first electrode configured to make ohmic contact with the anterior grid and a second electrode configured to make ohmic contact with the posterior grid,
a sensor wetting circuit comprising a microcontroller and a wireless transmitter, the sensor wetting circuit in electrical communication with said first electrode and said second electrode, the sensor wetting circuit configured to measure a change in an electrical property between said first electrode and the second electrode;
wherein upon exposure to a fluid on the anterior surface or the posterior surface of said substrate, an electrically conductive pathway is formed between the anterior grid and the posterior grid through at least one through substrate via of the plurality of through substrate vias, wherein a change in an electrical property between the said first electrode and said second electrode, as measured by said sensor wetting circuit, generates a signal to transmit via the wireless transmitter to the base station hub to the remote server and to the software application to indicate the detection of a leak.
